(19) United States
(12) Patent Application Publication
(10) Pub. No.: US 2012/0195128 A1
(43) Pub. Date: Aug. 2, 2012

(54) NONVOLATILE SEMICONDUCTOR MEMORY DEVICE AND METHOD FOR DRIVING THE SAME

(75) Inventors: Tomoko FUJIWARA, Kanagawa-ken (JP); Masaru Kito, Mie-ken (JP); Yoshiaki Fukuzumi, Kanagawa-ken (JP); Hideaki Aochi, Kanagawa-ken (JP)

(73) Assignee: Kabushiki Kaisha Toshiba, Tokyo (JP)

(21) Appl. No.: 13/177,719

(22) Filed: Jul. 7, 2011

(30) Foreign Application Priority Data
Jan. 31, 2011 (JP) 2011-017709

(51) Int. Cl. G11C 16/10

(52) U.S. Cl. 365/185.24

(57) ABSTRACT

According to one embodiment, a nonvolatile semiconductor memory device includes a memory unit and a control unit. The memory unit includes a multilayer structure, a semiconductor pillar, a storage layer, an inner insulating film, an outer insulating film, a memory cell transistor. The control unit performs control of setting the thresholds of the memory transistor to either positive or negative, and performs control so that, with one of the thresholds most distant from 0 volts being defined as n-th threshold, width of distribution of m-th threshold (m being an integer of 1 or more smaller than n) having a sign being same as the n-th threshold is set narrower than width of distribution of the n-th threshold.

### CROSS-REFERENCE TO RELATED APPLICATIONS

This application is based upon and claims the benefit of priority from the prior Japanese Patent Application No. 2011-017709, filed on Jan. 31, 2011; the entire contents of which are incorporated herein by reference.

### FIELD

Embodiments described herein relate generally to a nonvolatile semiconductor memory device and a method for driving the same.

### BACKGROUND

In order to increase the memory capacity of a nonvolatile semiconductor memory device (memory), it is necessary to reduce the dimension of one element. A collectively processed three-dimensional multilayer memory cell has been proposed to resolve the cost and technological difficulty associated with the miniaturization of elements.

In this collectively processed three-dimensional multilayer memory, insulating films are alternately stacked with electrode films (serving as word lines) to form a multilayer body. In this multilayer body, through holes are collectively formed. Then, a charge storage layer (storage layer) is formed on the side surface of the through hole. Silicon is buried inside the through hole to form a silicon pillar. A tunnel insulating film is provided between the charge storage layer and the silicon pillar. A block insulating film is provided between the charge storage layer and the electrode film. Thus, a memory cell (memory cell transistor) made of e.g. a MONOS (metal oxide nitride oxide semiconductor) transistor is formed at the intersection of each electrode film and the silicon pillar.

In the collectively processed three-dimensional multilayer memory, a threshold corresponding to n-valued information (n being an integer of 2 or more) is set to the memory cell transistor. In this case, the n thresholds are placed in the same polarity to prevent the degradation of charge retention characteristics.

In such a nonvolatile semiconductor memory device, further improvement is desired in terms of reducing the setting time of the threshold and suppressing the read voltage.

### BRIEF DESCRIPTION OF THE DRAWINGS

FIG. 1 is a schematic block diagram illustrating the configuration of a nonvolatile semiconductor storage device according to an embodiment;

FIG. 2 is a schematic sectional view illustrating the overall configuration of the nonvolatile semiconductor storage device according to the embodiment;

FIG. 3 is a schematic perspective view illustrating the configuration of the nonvolatile semiconductor storage device according to the embodiment;

FIG. 4 is a schematic sectional view illustrating a partial configuration of the nonvolatile semiconductor storage device according to the embodiment;

FIG. 5 is a schematic plan view illustrating the configuration of the electrode films of the nonvolatile semiconductor storage device according to the embodiment;

FIG. 6 describes a first embodiment

FIGS. 7A to 7D illustrate distributions of thresholds of the reference examples and the embodiment;

FIGS. 8A to 10B describe the method for driving the nonvolatile semiconductor storage device;

FIG. 11 is a circuit diagram describing the driving circuit configuration of the nonvolatile semiconductor storage device according to the embodiment; and

FIGS. 12A and 12B illustrate distributions in the case of setting four thresholds.

### DETAILED DESCRIPTION

In general, according to one embodiment, a nonvolatile semiconductor memory device includes a memory unit and a control unit. The memory unit includes a multilayer structure, a semiconductor pillar, a storage layer, an inner insulating film, an outer insulating film, a memory cell transistor. The multilayer structure includes a plurality of electrode films and a plurality of interelectrode insulating films alternately stacked in a first direction. The semiconductor pillar penetrates through the multilayer structure in the first direction. The storage layer is provided between each of the electrode films and the semiconductor pillar. An inner insulating film is provided between the storage layer and the semiconductor pillar. An outer insulating film is provided between each of the electrode films and the storage layer. Thresholds corresponding to n-valued information (n being an integer of 2 or more) are set to the memory cell transistor in response to charge accumulated in the storage layer. The control unit performs control of setting the thresholds to either positive or negative, and performs control so that, with one of the thresholds most distant from 0 volts being defined as n-th threshold, width of distribution of m-th threshold (m being an integer of 1 or more smaller than n) having a sign being same as the n-th threshold is set narrower than width of distribution of the n-th threshold.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the specification and the drawings, components similar to those described previously with reference to earlier figures are labeled with like reference numerals, and the detailed description thereof is omitted as appropriate.

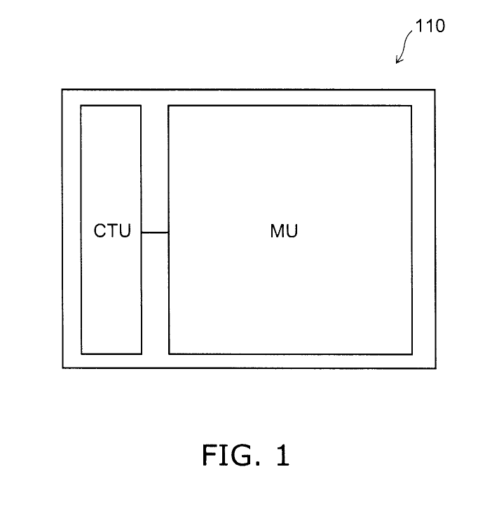

FIG. 1 is a schematic block diagram illustrating the configuration of a nonvolatile semiconductor memory device according to an embodiment.

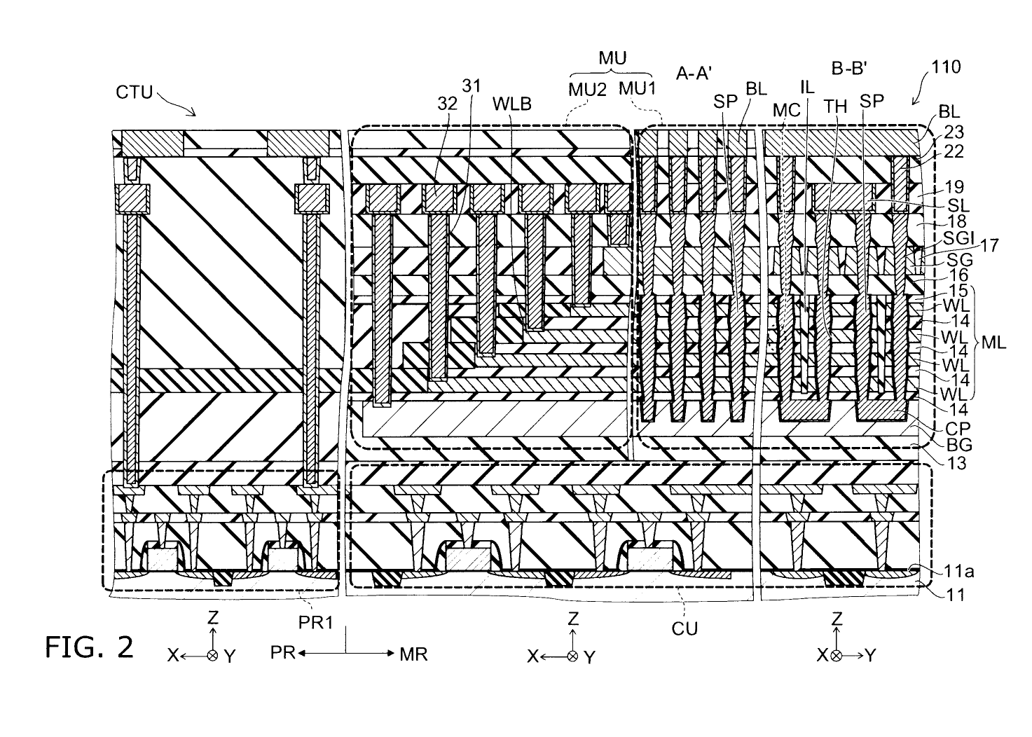

FIG. 2 is a schematic sectional view illustrating the overall configuration of the nonvolatile semiconductor memory device according to the embodiment.

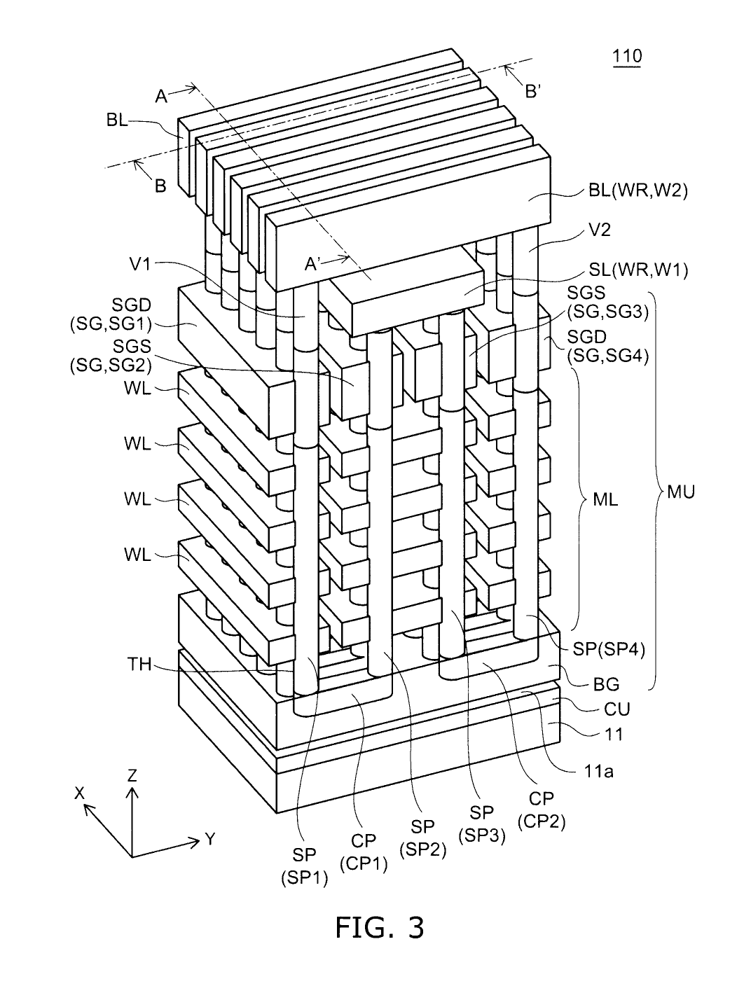

FIG. 3 is a schematic perspective view illustrating the configuration of the nonvolatile semiconductor memory device according to the embodiment.

For clarity of illustration, FIG. 3 shows only the conductive portions, and omits the insulating portions.

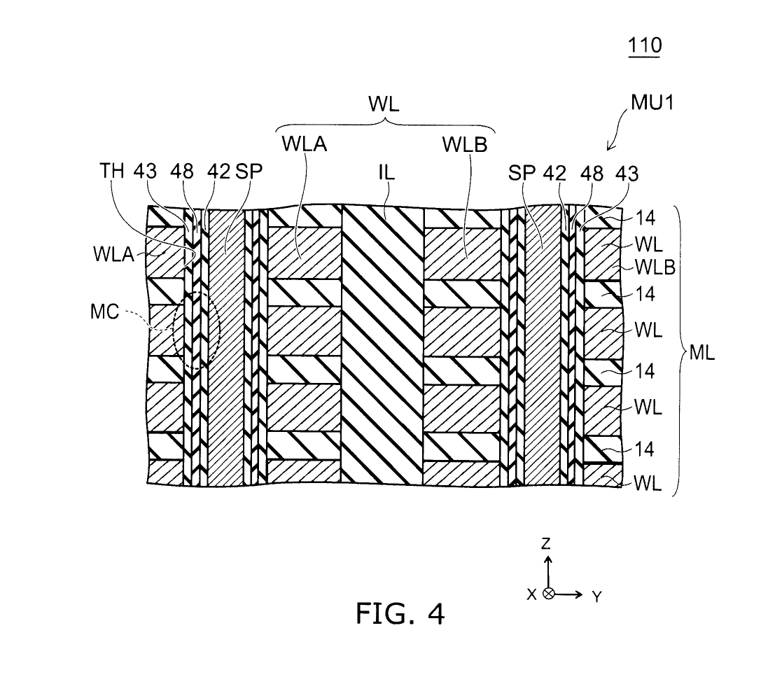

FIG. 4 is a schematic sectional view illustrating a partial configuration of the nonvolatile semiconductor memory device according to the embodiment.

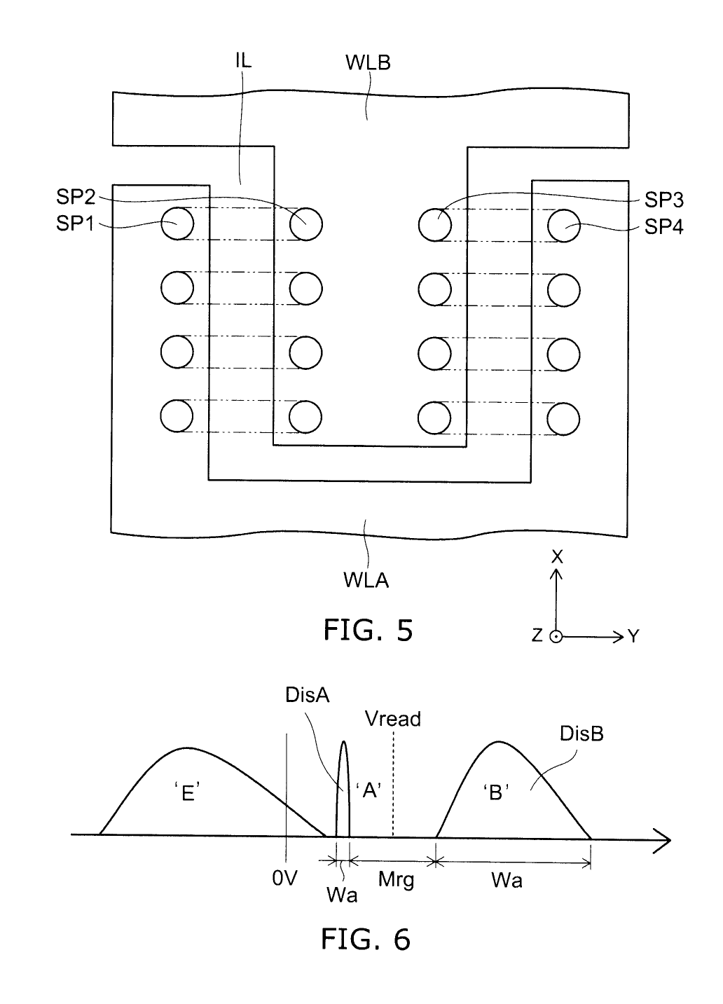

FIG. 5 is a schematic plan view illustrating the configuration of the electrode films of the nonvolatile semiconductor memory device according to the embodiment.

As shown in FIG. 1, the nonvolatile semiconductor memory device 110 according to the embodiment includes a memory unit MU and a control unit CTU. As shown in FIG. 4, the memory unit MU includes a charge storage film (storage layer) 48 and a plurality of memory cell transistors Tr connected in series. A threshold is set to the memory cell transistor Tr in response to the charge accumulated in the memory region of the charge storage film 48 corresponding to the memory cell transistor Tr.

The threshold is a voltage value corresponding to n-valued information (n being an integer of 2 or more). In programming information of one of the n values to the memory cell transistor Tr, the control unit CTU performs control of setting a threshold associated with that information to the memory cell transistor Tr.

The control unit CTU performs programming and reading of information per prescribed unit (page). The correlation between the threshold and the number of memory cell transistors Tr in the same page is expressed as distributions.

In addition to setting a threshold to the memory cell transistor Tr, the control unit CTU also performs control on the width of the distribution of this threshold. In the nonvolatile semiconductor memory device 110 according to the embodiment, the control unit CTU performs control of setting the thresholds associated with n-valued information to either positive or negative. Furthermore, of all the thresholds, the threshold most distant from 0 volts (V) is defined as the n-th threshold. The control unit CTU performs control so that the width of m-th distributions corresponding to m-th thresholds other than the n-th threshold (m being an integer of 1 or more smaller than n) is set narrower than the width of the n-th distribution corresponding to the n-th threshold.

The control operation of the control unit CTU is described later.

The nonvolatile semiconductor memory device 110 according to the embodiment is e.g. a three-dimensional multilayer flash memory. The configuration of the nonvolatile semiconductor memory device 110 is outlined with reference to FIGS. 2 to 5.

As shown in FIG. 2, the nonvolatile semiconductor memory device 110 includes the memory unit MU and the control unit CTU. The memory unit MU and the control unit CTU are provided on the major surface 11a of a semiconductor substrate 11 made of e.g. single crystal silicon. However, the control unit CTU may be provided on a substrate different from the substrate on which the memory unit MU is provided. In the following description, it is assumed that the memory unit MU and the control unit CTU are provided on the same substrate (semiconductor substrate 11).

On the semiconductor substrate 11, for instance, a memory array region MR including memory cells MC, and a peripheral region PR provided e.g. around the memory array region MR are defined. In the peripheral region PR, various peripheral region circuits PR1 are provided on the semiconductor substrate 11.

In the memory array region MR, a circuit unit CU, for instance, is provided on the semiconductor substrate 11. The memory unit MU is provided on the circuit unit CU. It is noted that the circuit unit CU is provided as needed, and can be omitted. An interlayer insulating film 13 made of e.g. silicon oxide is provided between the circuit unit CU and the memory unit MU.

At least part of the control unit CTU can be provided, for instance, in at least one of the peripheral region circuit PR1 and the circuit unit CU described above.

The memory unit MU includes a matrix memory cell unit MU1 including a plurality of memory cell transistors, and an interconnection connecting unit MU2 for connecting interconnections in the matrix memory cell unit MU1.

FIG. 3 illustrates the configuration of the matrix memory cell unit MU1.

More specifically, with regard to the matrix memory cell unit MU1, FIG. 2 illustrates part of the A-A′ cross section of FIG. 3 and part of the B-B′ cross section of FIG. 3.

As shown in FIGS. 2 and 3, in the matrix memory cell unit MU1, a multilayer structure ML is provided on the major surface 11a of the semiconductor substrate 11. The multilayer structure ML includes a plurality of electrode films WL and a plurality of interelectrode insulating films 14 alternately stacked in the direction perpendicular to the major surface 11a.

Here, for convenience of description, an XYZ orthogonal coordinate system is herein introduced. In this coordinate system, the direction perpendicular to the major surface 11a of the semiconductor substrate 11 is referred to as Z-axis direction (first direction). One of the directions in the plane parallel to the major surface 11a is referred to as Y-axis direction. The direction perpendicular to the Z axis and the Y axis is referred to as X-axis direction.

The stacking direction of the electrode films WL and the interelectrode insulating films 14 in the multilayer structure ML is the Z-axis direction. That is, the electrode films WL and the interelectrode insulating films 14 are provided parallel to the major surface 11a.

FIG. 4 illustrates the configuration of the matrix memory cell unit MU1. For instance, FIG. 4 corresponds to part of the B-B′ cross section of FIG. 3.

As shown in FIGS. 3 and 4, the memory unit MU of the nonvolatile semiconductor memory device 110 includes the aforementioned multilayer structure ML, a semiconductor pillar SP (first semiconductor pillar SP1) as a semiconductor portion penetrating through the multilayer structure ML in the Z-axis direction, a charge storage film 48, an inner insulating film 42, an outer insulating film 43, and interconnections WR.

The charge storage film 48 is provided between each electrode film WL and the semiconductor pillar SP. The inner insulating film 42 is provided between the charge storage film 48 and the semiconductor pillar SP. The outer insulating film 43 is provided between each electrode film WL and the charge storage film 48. The interconnection WR is electrically connected to one end of the semiconductor pillar SP.

More specifically, the outer insulating film 43, the charge storage film 48, and the inner insulating film 42 are formed in this order on the inner wall surface of a through hole TH penetrating through the multilayer structure ML in the Z-axis direction. A semiconductor is buried in the remaining space to form the semiconductor pillar SP.

A memory cell MC is provided at the intersection between the electrode film WL of the multilayer structure ML and the semiconductor pillar SP. That is, memory cell transistors Tr including the charge storage film 48 are provided in a three-dimensional matrix, each at the intersection of the electrode film WL and the semiconductor pillar SP. Each memory cell transistor Tr functions as a memory cell MC for storing data by accumulating charge in the charge storage film 48. Hence, the position of the electrode film WL in the charge storage film 48 of the memory cell MC functions as a memory region. Thus, a plurality of memory regions are provided along the charge storage film 48.

The inner insulating film 42 functions as a tunnel insulating film in the memory cell transistor of the memory cell MC. On the other hand, the outer insulating film 43 functions as a block insulating film in the memory cell transistor of the memory cell MC. The interelectrode insulating film 14 functions as an interlayer insulating film for insulating the electrode films WL from each other.

The electrode film WL can be made of any conductive material, such as amorphous silicon or polysilicon provided with conductivity by impurity doping, or can be made of metals and alloys. The electrode film WL is applied with a prescribed electrical signal, and functions as a word line of the nonvolatile semiconductor memory device 110.

The interelectrode insulating film 14, the inner insulating film 42, and the outer insulating film 43 can be e.g. silicon oxide films. It is noted that the interelectrode insulating film 14, the inner insulating film 42, and the outer insulating film 43 may be a monolayer film or a multilayer film.

The charge storage film 48 can be e.g. a silicon nitride film. The charge storage film 48 functions as a portion for storing information by accumulating or releasing charge under an electric field applied between the semiconductor pillar SP and the electrode film WL. The charge storage film 48 may be a monolayer film or a multilayer film.

As described later, the interelectrode insulating film 14, the inner insulating film 42, the charge storage film 48, and the outer insulating film 43 can be made of various materials, not limited to the materials illustrated above.

Here, FIGS. 2 and 3 illustrate the case where the multilayer structure ML includes four electrode films WL. However, the number of electrode films WL provided in the multilayer structure ML is arbitrary. In the following description, it is assumed that the number of electrode films WL is four.

One semiconductor pillar SP constitutes an I-shaped NAND string. Here, two semiconductor pillars SP may be connected to each other on one end side to constitute a U-shaped NAND string. In the example, two semiconductor pillars SP are connected by a connecting portion CP (connecting portion semiconductor layer). More specifically, the memory unit MU further includes a second semiconductor pillar SP2 (semiconductor pillar SP) and a first connecting portion CP1 (connecting portion CP).

The second semiconductor pillar SP2 is adjacent to the first semiconductor pillar SP1 (semiconductor pillar SP) in e.g. the Y-axis direction and penetrates through the multilayer structure ML in the Z-axis direction. The first connecting portion CP1 electrically connects the first semiconductor pillar SP1 and the second semiconductor pillar SP2 on the same side (on the semiconductor substrate 11 side) in the Z-axis direction. The first connecting portion CP1 extends in the Y-axis direction. The first connecting portion CP1 is made of the same material as the first and second semiconductor pillar SP1 and SP2.

More specifically, a back gate BG (connecting portion conductive layer) is provided on the major surface 11a of the semiconductor substrate 11 via the interlayer insulating film 13. A trench (the trench CTR described later) is provided in portions of the back gate BG opposed to the first and second semiconductor pillar SP1 and SP2. An outer insulating film 43, a charge storage film 48, and an inner insulating film 42 are formed inside the trench. A connecting portion CP made of a semiconductor is buried in the remaining space of the trench. Here, the formation of the outer insulating film 43, the charge storage film 48, the inner insulating film 42, and the connecting portion CP in the aforementioned trench is performed simultaneously and collectively with the formation of the outer insulating film 43, the charge storage film 48, the inner insulating film 42, and the semiconductor pillar SP in the through hole TH. Thus, the back gate BG is provided opposite to the connecting portion CP.

Thus, the first semiconductor pillar SP1, the second semiconductor pillar SP2, and the connecting portion CP form a U-shaped semiconductor pillar. This constitutes a U-shaped NAND string.

The connecting portion CP has the function of electrically connecting the first semiconductor pillar SP1 and the second semiconductor pillar SP2. In addition, the connecting portion CP can also be used as one memory cell. Thus, the number of memory bits can be increased. However, in the following description, it is assumed that the connecting portion CP electrically connects the first semiconductor pillar SP1 and the second semiconductor pillar SP2, but is not used as a memory portion.

As shown in FIGS. 2 and 3, the end of the first semiconductor pillar SP1 opposite from the first connecting portion CP1 is connected to a bit line BL (second interconnection W2). The end of the second semiconductor pillar SP2 opposite from the first connecting portion CP1 is connected to a source line SL (first interconnection W1). Here, the semiconductor pillar SP is connected to the bit line BL by a via V1 and a via V2. The interconnections WR include the first interconnection W1 and the second interconnection W2.

In the example, the bit line BL extends in the Y-axis direction, and the source line SL extends in the X-axis direction.

Between the multilayer structure ML and the bit line BL, a drain side select gate electrode SGD (first select gate electrode SG1, or select gate electrode SG) is provided opposite to the first semiconductor pillar SP1, and a source side select gate electrode SGS (second select gate electrode SG2, or select gate electrode SG) is provided opposite to the second semiconductor pillar SP2. Thus, desired data can be programmed to and read from an arbitrary memory cell MC of an arbitrary semiconductor pillar SP.

The select gate electrode SG can be made of any conductive material, such as polysilicon or amorphous silicon. In the example, the select gate electrode SG is divided in the Y-axis direction and shaped like strips extending in the X-axis direction.

As shown in FIG. 2, an interlayer insulating film 15 is provided at the top (on the side farthest from the semiconductor substrate 11) of the multilayer structure ML. Furthermore, an interlayer insulating film 16 is provided on the multilayer structure ML, and a select gate electrode SG is provided thereon. An interlayer insulating film 17 is provided between the select gate electrodes SG. A through hole is provided in the select gate electrode SG. A select gate insulating film SGI of a select gate transistor is provided on the inner side surface of the through hole, and a semiconductor is buried inside it. This semiconductor is connected to the semiconductor pillar SP. That is, the memory unit MU further includes a select gate electrode SG stacked on the multilayer structure ML in the Z-axis direction and penetrated by the semiconductor pillar SP on the interconnection WR side (at least one of the source line SL side and the bit line BL side).

Furthermore, an interlayer insulating film 18 is provided on the interlayer insulating film 17, and a source line SL and vias 22 (vias V1, V2) are provided thereon. An interlayer insulating film 19 is provided around the source line SL. Furthermore, an interlayer insulating film 23 is provided on the source line SL, and a bit line BL is provided thereon. The bit line BL is shaped like a strip along the Y axis.

The interlayer insulating films 15, 16, 17, 18, 19, and 23, and the select gate insulating film SGI can be made of e.g. silicon oxide.

Here, with regard to the plurality of semiconductor pillars provided in the nonvolatile semiconductor memory device 110, when all or any of the semiconductor pillars are referred to, the wording “semiconductor pillar SP” is used. On the other hand, when a particular semiconductor pillar is referred to in describing the relationship between the semiconductor pillars, for instance, the wording “k-th semiconductor pillar SPk” (k is any integer of one or more) is used.

As shown in FIG. 5, for j being an integer of zero or more, the electrode films WL corresponding to the semiconductor pillars SP(4j+1) and SP(4j+4) with k being equal to 4j+1 and 4j+4 are commonly connected into an electrode film WLA. The electrode films corresponding to the semiconductor pillars SP(4j+2) and SP(4j+3) with k being equal to 4j+2 and 4j+3 are commonly connected into an electrode film WLB. That is, the electrode films WL are shaped into the electrode film WLA and the electrode film WLB which are opposed in the X-axis direction and meshed with each other like comb teeth.

As shown in FIGS. 4 and 5, the electrode film WL is divided by an insulating layer IL into a first region (electrode film WLA) and a second region (electrode film WLB).

Furthermore, as in the interconnection connecting unit MU2 illustrated in FIG. 2, at one end in the X-axis direction, the electrode film WLB is connected to a word interconnection 32 by a via plug 31 and electrically connected to, for instance, a driving circuit provided in the semiconductor substrate 11. Likewise, at the other end in the X-axis direction, the electrode film WLA is connected to a word interconnection by a via plug and electrically connected to a driving circuit. That is, the length in the X-axis direction of the electrode films WL (electrode film WLA and electrode film WLB) stacked in the Z-axis direction is varied stepwise, so that electrical connection to the driving circuit is implemented by the electrode film WLA at one end in the X-axis direction and by the electrode film WLB at the other end in the X-axis direction.

As shown in FIG. 3, the memory unit MU can further include a third semiconductor pillar SP3 (semiconductor pillar SP), a fourth semiconductor pillar SP4 (semiconductor pillar SP), and a second connecting portion CP2 (connecting portion CP).

The third semiconductor pillar SP3 is adjacent to the second semiconductor pillar SP2 on the opposite side of the second semiconductor pillar SP2 from the first semiconductor pillar SP1 in the Y-axis direction and penetrates through the multilayer structure ML in the Z-axis direction. The fourth semiconductor pillar SP4 is adjacent to the third semiconductor pillar SP3 on the opposite side of the third semiconductor pillar SP3 from the second semiconductor pillar SP2 in the Y-axis direction and penetrates through the multilayer structure ML in the Z-axis direction.

The second connecting portion CP2 electrically connects the third semiconductor pillar SP3 and the fourth semiconductor pillar SP4 on the same side (as the first connecting portion CP1) in the Z-axis direction. The second connecting portion CP2 extends in the Y-axis direction and is opposed to the back gate BG.

The charge storage film 48 is provided also between each electrode film WL and the third and fourth semiconductor pillar SP3 and SP4, and between the back gate BG and the second connecting portion CP2. The inner insulating film 42 is provided also between the charge storage film 48 and the third and fourth semiconductor pillar SP3 and SP4, and between the charge storage film 48 and the second connecting portion CP2. The outer insulating film 43 is provided also between each electrode film WL and the charge storage film 48, and between the charge storage film 48 and the back gate BG.

The source line SL is connected to the third end portion of the third semiconductor pillar SP3 opposite from the second connecting portion CP2. The bit line BL is connected to the fourth end portion of the fourth semiconductor pillar SP4 opposite from the second connecting portion CP2.

Furthermore, a source side select gate electrode SGS (third select gate electrode SG3, or select gate electrode SG) is provided opposite to the third semiconductor pillar SP3. A drain side select gate electrode SGD (fourth select gate electrode SG4, or select gate electrode SG) is provided opposite to the fourth semiconductor pillar SP4.

Next, a specific embodiment is described. One memory cell can record n-valued information (n being an integer of 2 or more). In the following, for clarity of description, an example of n=2, that is, an example of recording binary information, is taken. The thresholds of the memory cell transistor corresponding to this binary information are denoted by A and B. In erasing the information in the memory cell, the threshold of the memory cell transistor corresponding to the erase information is denoted by E. Furthermore, thresholds of the memory cell transistor corresponding to information other than the binary information and the erase information are denoted by symbols other than A, B, and E.

FIG. 6 describes a first embodiment.

More specifically, FIG. 6 schematically shows distributions of thresholds of the memory cell transistor Tr.

In the nonvolatile semiconductor memory device 110 according to the embodiment, the control unit CTU sets the thresholds A and B to either positive or negative. In the example shown in FIG. 6, the thresholds A and B are set to the positive side. The erase threshold E is set so as to be opposite in sign to the thresholds A and B. Setting the thresholds A and B to the same sign prevents the degradation of charge retention characteristics in the charge storage film 48.

The control unit CTU performs control of setting the width of the distribution of the threshold A narrower than the width of the distribution of the threshold B. In the case where the number of thresholds is n, the threshold most distant from 0 V is defined as the n-th threshold. Control is performed so that the width of the distributions of the m-th thresholds (n*m) other than the erase threshold E is set narrower than the width of the n-th distribution of the n-th threshold.

Specifically, of the thresholds A and B, the threshold B is the most distant from 0 V. The control unit CTU performs control so that the width Wa of the distribution DisA of the threshold A other than the threshold B is set narrower than the width Wb of the distribution DisB of the threshold B.

Here, the width of the distribution refers to the voltage difference at the tail of the distribution.

Thus, the spacing Mrg between the distribution DisA and the distribution DisB is made wider than in the case where the width Wa is nearly equal to the width Wb. If the spacing Mrg is made wider, the read voltage Vread can be set lower. More specifically, the read voltage Vread for the thresholds A and B is set in the spacing Mrg. If the spacing Mrg is made wider, the voltage Vread can be made close to the distribution DisA. As a result, the read voltage Vread can be set lower.

In the embodiment, as an example, the width Wa is set to half or less of the width Wb. More preferably, the width Wa is set to ⅓ or less of the width Wb. Thus, the read voltage Vread can be sufficiently lowered.

Here, comparison of the embodiment with reference examples is described.

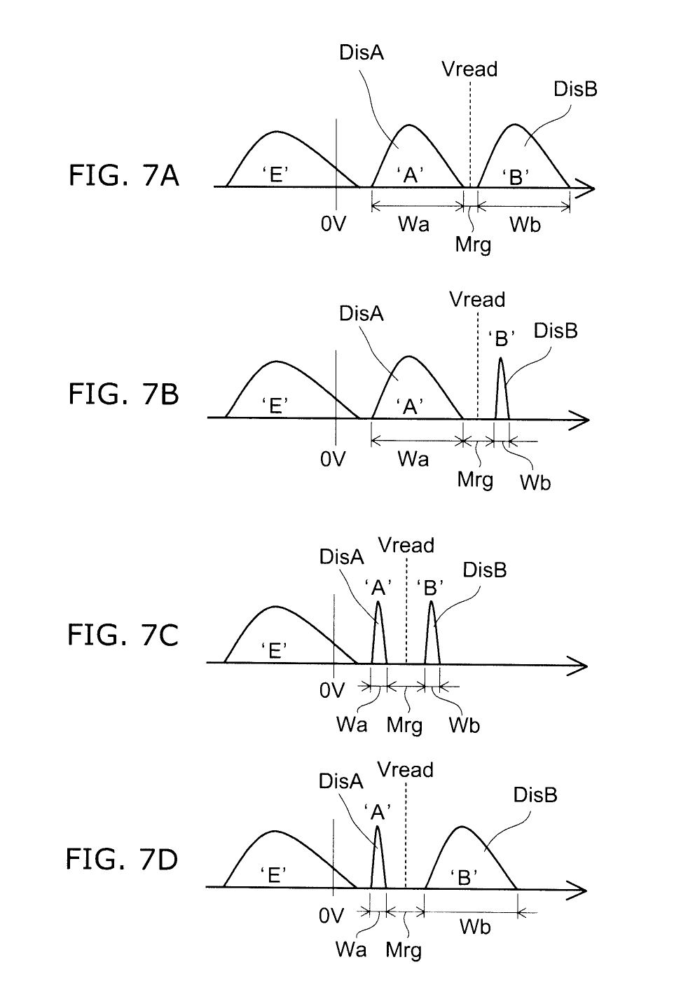

FIGS. 7A to 7D illustrate distributions of thresholds of the reference examples and the embodiment.

More specifically, FIGS. 7A to 7C illustrate distributions of thresholds of the reference examples, and FIG. 7D illustrate distributions of thresholds of the embodiment.

In the reference example shown in FIG. 7A, the width Wa of the distribution DisA of the threshold A is nearly equal to the width Wb of the distribution DisB of the threshold B.

When the control unit programs a threshold to the memory cell transistor, the control unit performs driving so that the application voltage is incrementally raised. Specifically, a program verify operation is performed. In the program verify operation, programming is repeated until the memory cell transistor reaches a threshold voltage equal to or greater than the program verify voltage. The distribution of the threshold is made narrower with the increase of the number of times of programming by the verify operation (the number of voltage applications).

In the reference example shown in FIG. 7A, the widths Wa and Wb of the distributions DisA and DisB are relatively wide, and the spacing Mrg is narrow. Hence, to accurately discriminate the thresholds A and B, the read voltage Vread needs to be raised.

In the reference example shown in FIG. 7B, the width Wb of the distribution DisB of the threshold B is made narrower than in the reference example shown in FIG. 7A. In this reference example, the spacing Mrg between the distribution DisA of the threshold A and the distribution DisB of the threshold B is made wider than in the reference example shown in FIG. 7A. However, in the distribution DisA of the threshold A, the tail on the threshold B side is difficult to control. Thus, the spacing Mrg between the distribution DisA of the threshold A and the distribution DisB of the threshold B cannot be effectively utilized. Hence, the read voltage Vread cannot be sufficiently lowered.

In the reference example shown in FIG. 7C, the widths Wa and Wb of the distributions DisA and DisB of the thresholds A and B, respectively, are made narrower than in the reference example shown in FIG. 7A. Thus, the spacing Mrg between the distribution DisA of the threshold A and the distribution DisB of the threshold B is expanded, and the read voltage Vread can also be lowered. However, the number of times of programming by the verify operation for each of the threshold A and the threshold B increases. This causes the delay of the threshold setting (programming) time.

As shown in FIG. 7D, in the embodiment, the width Wa of the distribution DisA of the threshold A is made narrower than the width Wb of the distribution DisB of the threshold B. Thus, the spacing Mrg between the distribution DisA and the distribution DisB can be made wider than in the reference example shown in FIG. 7A. Furthermore, the tail of the distribution DisA of the threshold A on the threshold B side is accurately controlled, and the spacing Mrg can be effectively utilized. Hence, the read voltage Vread can be sufficiently lowered. Furthermore, in the embodiment, the number of times of programming by the verify operation needs to be increased only for the threshold A. Thus, the programming time can be made shorter than in the reference example shown in FIG. 7C.

Thus, in the embodiment, when the thresholds A and B are set to the positive side, the read voltage Vread can be lowered while suppressing the increase of the number of times of programming by the verify operation.

Next, a method for driving the nonvolatile semiconductor memory device 110 is described.

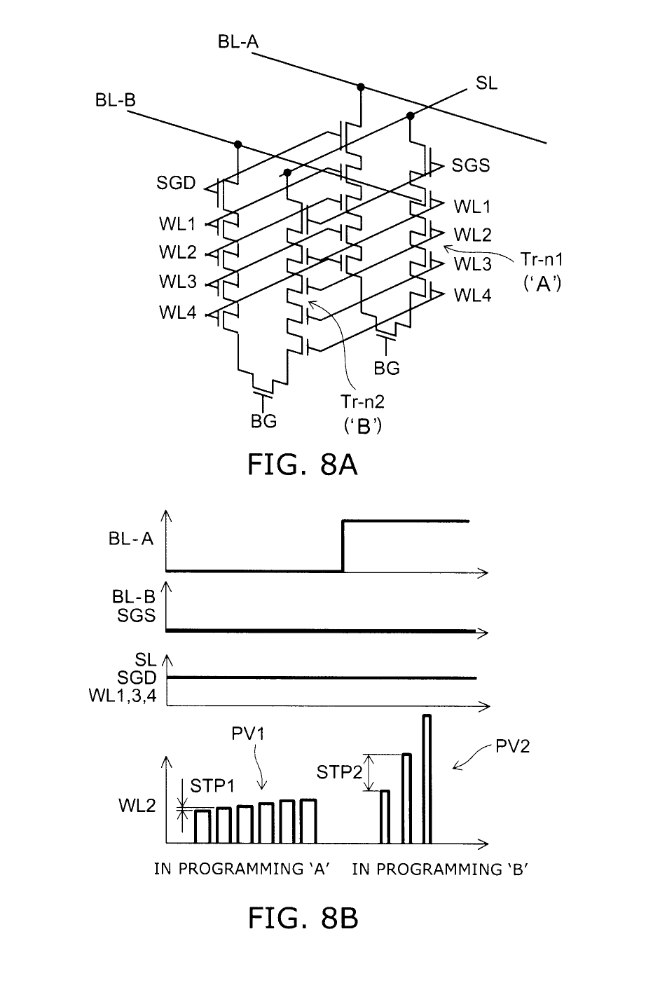

FIGS. 8A to 10B describe the method for driving the nonvolatile semiconductor memory device.

More specifically, FIGS. 8A to 10B shows an equivalent circuit of U-shaped NAND strings. Here, for clarity of description, the following description is based on an example of setting thresholds to two memory cell transistors Tr-n1 and Tr-n2 corresponding to the same electrode film WL in two U-shaped NAND strings.

First, with reference to FIGS. 8A and 8B, the case of setting a threshold A to the memory cell transistor Tr-n1 and setting a threshold B to the memory cell transistor Tr-n2 is described. Here, FIG. 8A schematically shows an equivalent circuit, and FIG. 8B schematically shows the timing of voltage application to each interconnection.

The control unit CTU first applies a voltage for the threshold A to the electrode film WL2 common to the memory cell transistors Tr-n1 and Tr-n2. The control unit CTU supplies an incrementally increasing pulse voltage PV1 as the voltage for the threshold A applied to the electrode film WL2. This pulse voltage PV1 increases in increments of a variation STP1. The control unit CTU supplies the incrementally increasing pulse voltage PV1 until the threshold of the memory cell transistor Tr-n1 reaches a threshold voltage equal to or greater than the program verify voltage.

At this time, the control unit CTU programs the threshold A also to the memory cell transistor Tr-n2. Furthermore, the bit lines BL-A and BL-B of the cells to be programmed are set to 0V. The drain side select gate electrode SGD, and the electrode films WL1, WL3, and WL4 not to be programmed, are applied with a Vpass voltage (e.g., 3 V).

Furthermore, the source line SL is applied with the same voltage as the Vpass voltage (e.g., 3 V), and the source side select gate electrode SGS is set to 0 V, so that programming is not performed from the source line SL side.

Next, after programming the threshold A, the control unit CTU raises the bit line BL-A of the memory cell transistor Tr-n1 programmed with the threshold A to the same voltage as the Vpass voltage (e.g., 3 V), so that programming is not performed on the memory cell transistor Tr-n1. Then, a voltage for the threshold B is applied to the electrode film WL2. The control unit CTU supplies an incrementally increasing pulse voltage PV2 as the voltage for the threshold B applied to the electrode film WL2. This pulse voltage PV2 increases in increments of a variation STP2. The control unit CTU supplies the incrementally increasing pulse voltage PV2 until the threshold of the memory cell transistor Tr-n2 reaches a threshold voltage equal to or greater than the program verify voltage.

At this time, the memory cell transistor Tr-n2 has already reached the threshold A. Hence, the pulse voltage PV2 reaches the desired threshold B by a smaller number of pulses than the pulse voltage PV1. In the embodiment, the width Wa of the distribution DisA of the threshold A is narrower than the width Wb of the distribution DisB of the threshold B. Hence, the number of pulses (the number of applications) of the pulse voltage PV1 is smaller than the number of pulses (the number of applications) of the pulse voltage PV2. Furthermore, the variation STP1 of the pulse voltage PV1 is smaller than the variation STP2 of the pulse voltage PV2. Furthermore, the width of one pulse of the pulse voltage PV2 is narrower than the width of one pulse of the pulse voltage PV1.

By such programming, in the memory cell transistor Tr of the memory unit MU, the width Wa of the distribution DisA of the threshold A is set narrower than the width Wb of the distribution DisB of the threshold B. Hence, the read voltage Vread can be lowered while suppressing the increase of the number of times of programming by the verify operation for the thresholds A and B.

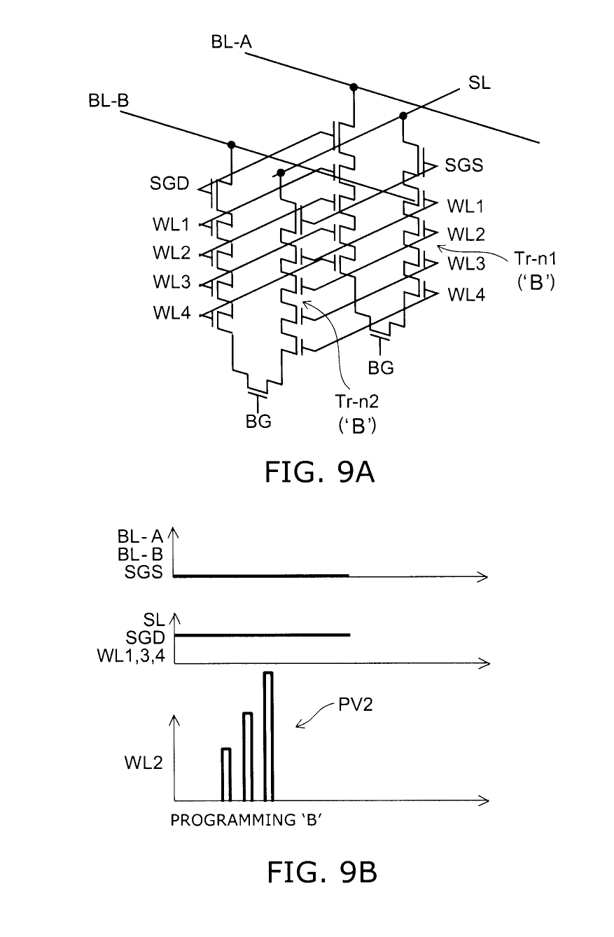

Next, with reference to FIGS. 9A and 9B, the case of setting the threshold B to the memory cell transistors Tr-n1 and Tr-n2 is described. Here, FIG. 9A schematically shows an equivalent circuit, and FIG. 9B schematically shows the timing of voltage application to each interconnection.

The control unit CTU applies a voltage for the threshold B (pulse voltage PV2) to the memory cell transistors Tr-n1 and Tr-n2 from the beginning. At this time, the bit lines BL-A and BL-B of the transistors Tr-n1 and Tr-n2 to be programmed are all set to 0 V. The drain side select gate electrode SGD, and the electrode films WL1, WL3, and WL4 not to be programmed, are applied with a Vpass voltage (e.g., 3 V). Also in this case, like the foregoing, the source line SL is applied with the same voltage as the Vpass voltage (e.g., 3 V), and the source side select gate electrode SGS is set to 0 V, so that programming is not performed from the source line SL side.

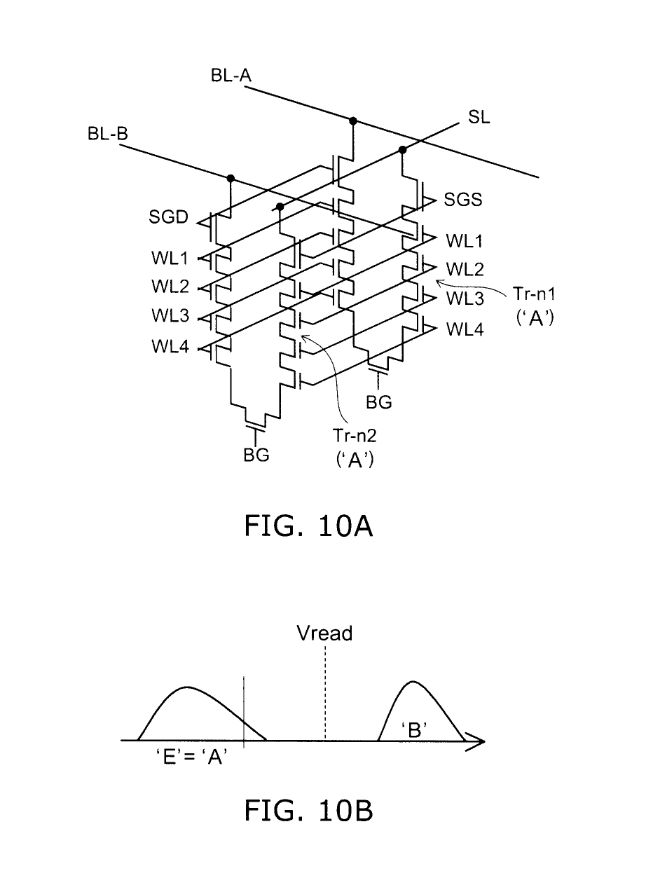

Next, with reference to FIGS. 10A and 10B, the case of setting the threshold A to the memory cell transistors Tr-n1 and Tr-n2 is described. Here, FIG. 10A schematically shows an equivalent circuit, and FIG. 10B schematically shows the distributions of thresholds.

In the case of setting the threshold A to the memory cell transistors Tr-n1 and Tr-n2, the control unit CTU leaves the erase threshold E as it is. That is, as shown in FIG. 10B, the threshold A can be determined if the threshold is lower than the read voltage Vread. Hence, the erase threshold E can be regarded as the threshold A. Hence, no verify operation of the voltage for the threshold A (pulse voltage PV1) is performed. Thus, the delay of the programming time can be suppressed.

By the driving method as described above, the read voltage Vread can be lowered while suppressing the increase of the number of times of programming by the verify operation for the thresholds A and B.

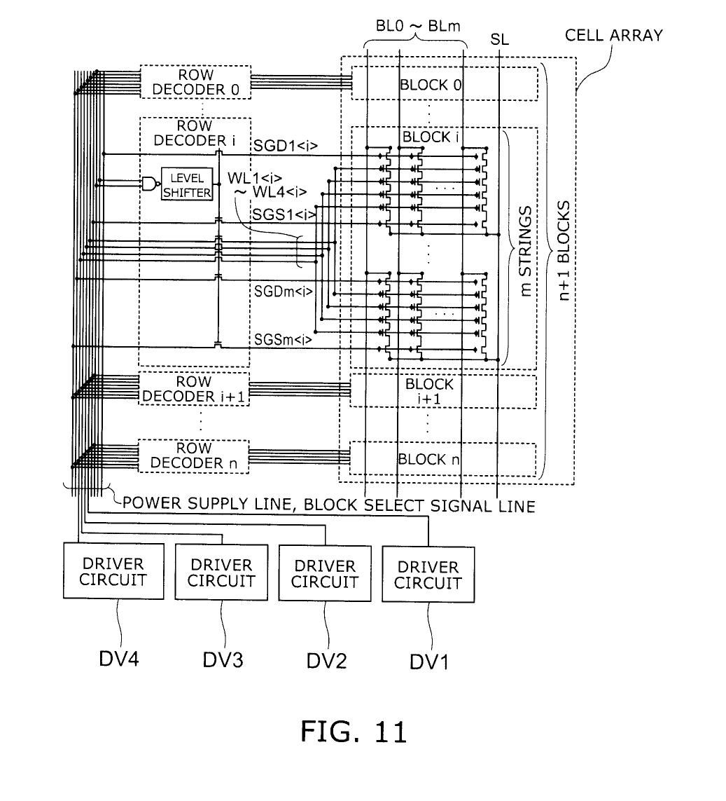

FIG. 11 is a circuit diagram describing the driving circuit configuration of the nonvolatile semiconductor memory device according to the embodiment. More specifically, the nonvolatile semiconductor memory device includes a cell array and decoders. The cell array includes n blocks (in FIG. 11 and its description, n being an integer of 1 or more), each including m strings (in FIG. 11 and its description, m being an integer of 1 or more). One string includes a plurality of memory cells. Memory cell transistors in each memory cell are connected in series. The memory cell transistor is configured so that its threshold is varied by information set to the memory cell.

The decoder is a row decoder. Each block of the cell array is provided with n row decoders. That is, block 0 corresponds to row decoder 0, block 1 corresponds to row decoder 1, . . . , block i corresponds to row decoder i, . . . , and block n corresponds to row decoder n.

Row decoder i connected to block i supplies the drain side select gate electrodes SGD of the m strings of block i with signals SGD1<i>-SGDm<i>, and supplies the source side select gate electrodes SGS with signals SGS1<i>-SGSm<i>. Furthermore, row decoder i supplies signals to the electrode film WL of block i on a layer-by-layer basis. In the example shown in FIG. 11, there are four electrode films WL. Hence, signals WL1<i>-WL4<i> are supplied. Each row decoder other than row decoder i has a similar configuration, and supplies the corresponding block with signals similar to the foregoing.

Bit lines BL0-BLm common to the m strings of each block are connected to blocks 0-n of the cell array. A common source line SL is connected to the blocks.

Control of signals sent to the bit lines BL0-BLm and the source line SL, and control of the row decoders are performed by driver circuits DV1-DV4. The driver circuits DV1-DV4 are circuits for controlling signals WL1<i>-WL4<i> in each block 0-n. The driver circuit DV1 controls the signal WL1<i> of each block 0-n. The driver circuit DV2 controls the signal WL2<i> of each block 0-n. The driver circuit DV3 controls the signal WL3<i> of each block 0-n. The driver circuit DV4 controls the signal WL4<i> of each block 0-n. The signals outputted from the driver circuits DV1-DV4 are sent via the row decoders 0-n as signals WL1<i>-WL4<i> of each block 0-n.

The driver circuit may be provided in the same chip as the nonvolatile semiconductor memory device, or outside the chip.

The above embodiment has been described primarily with reference to the example of a nonvolatile semiconductor memory device including a U-shaped NAND string in which two semiconductor pillars are connected by a connecting portion. However, the embodiment is also applicable to a nonvolatile semiconductor memory device including an I-shaped NAND string with no connecting portion in which each semiconductor pillar is independent.

Furthermore, the above embodiment has been described with reference to the case of setting two thresholds A and B to the memory cell transistor Tr. However, the embodiment is similarly applicable to the case of setting three or more thresholds.

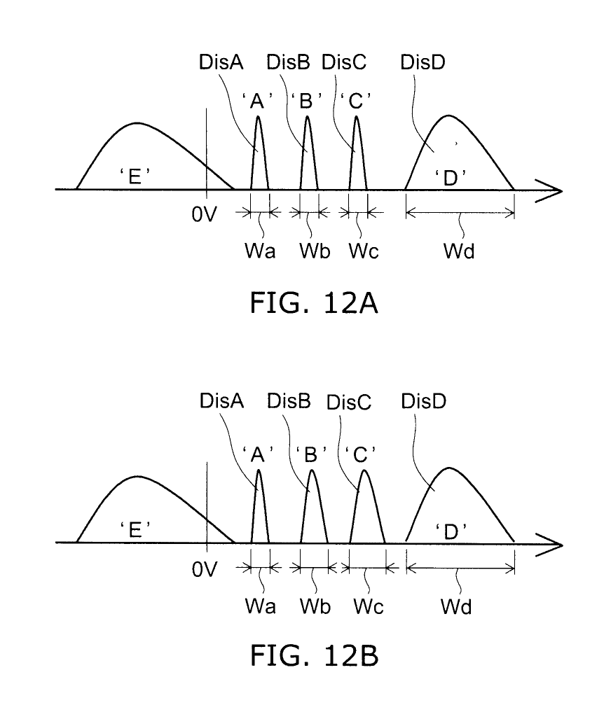

FIGS. 12A and 12B illustrate distributions in the case of setting four thresholds.

In the distributions shown in each of FIGS. 12A and 12B, of the thresholds A-D, the threshold D is the most distant from 0V. The control unit CTU performs control so that the widths Wa, Wb, and Wc of the distributions DisA, DisB, and DisC of the thresholds A, B, and C other than the threshold D are set narrower than the width Wd of the distribution DisD of the threshold D.

In the distributions shown in FIG. 12A, the widths Wa, Wb, and Wc are nearly equal. In the distributions shown in FIG. 12B, the widths Wa, Wb, and Wc are expanded in this order. Any size relation among the widths Wa, Wb, and Wc other than the foregoing examples is applicable as long as the widths Wa, Wb, and Wc are narrower than the width Wd. In any example, the widths Wa, Wb, and Wc are set by the number of times of verify programming and the setting of the read voltage Vread.

In the above embodiments, the n thresholds are set to the positive side, and the erase threshold is set to the negative side. However, conversely, the embodiments are similarly applicable to the case where the n thresholds are set to the negative side, and the erase threshold is set to the positive side.

In the nonvolatile semiconductor memory device according to the embodiments, the interelectrode insulating film 14, the inner insulating film 42, and the outer insulating film 43 can be a single layer film made of a material selected from the group consisting of silicon oxide, silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

Furthermore, the charge storage film 48 can be a single layer film made of a material selected from the group consisting of silicon nitride, silicon oxynitride, aluminum oxide, aluminum oxynitride, hafnia, hafnium aluminate, hafnia nitride, hafnium nitride aluminate, hafnium silicate, hafnium nitride silicate, lanthanum oxide, and lanthanum aluminate, or a multilayer film made of a plurality of materials selected from the group.

In the specification, “perpendicular” and “parallel” mean not only being exactly perpendicular and exactly parallel, but include, for instance, variations in the manufacturing process, and only need to mean substantially perpendicular and substantially parallel.

The embodiments of the invention have been described above with reference to examples. However, the invention is not limited to these examples. For instance, various specific configurations of the components, such as the semiconductor substrate, electrode film, insulating film, insulating layer, multilayer structure, storage layer, charge storage layer, semiconductor pillar, word line, bit line, source line, interconnection, memory cell transistor, and select gate transistor constituting the nonvolatile semiconductor memory device are encompassed within the scope of the invention as long as those skilled in the art can similarly practice the invention and achieve similar effects by suitably selecting such configurations from conventionally known ones.

Furthermore, any two or more components of the examples can be combined with each other as long as technically feasible, and such combinations are also encompassed within the scope of the invention as long as they fall within the spirit of the invention.

As described above, the nonvolatile semiconductor memory device 110 according to the embodiments can reduce the setting time of the threshold and suppress the read voltage when the threshold of the memory cell transistor Tr is set to either positive or negative.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device comprising:
a memory unit; and
a control unit,
the memory unit including:
a multilayer structure including a plurality of electrode films and a plurality of interelectrode insulating films alternately stacked in a first direction;
a semiconductor pillar penetrating through the multilayer structure in the first direction;
a storage layer provided between each of the electrode films and the semiconductor pillar;
an inner insulating film provided between the storage layer and the semiconductor pillar;
an outer insulating film provided between each of the electrode films and the storage layer; and
a memory cell transistor to which thresholds corresponding to n-valued information (n being an integer of 2 or more) are set in response to charge accumulated in the storage layer, and
the control unit performing control of setting the thresholds to either positive or negative, and performing control so that, with one of the thresholds most distant from 0 volts being defined as n-th threshold, width of distribution of m-th threshold (m being an integer of 1 or more smaller than n) having a sign being same as the n-th threshold is set narrower than width of distribution of the n-th threshold.

2. The device according to claim 1, wherein the control unit makes number of voltage applications to the memory cell transistor in setting the m-th threshold larger than number of voltage applications to the memory cell transistor in setting the n-th threshold.

3. The device according to claim 1, wherein the control unit performs control of setting the thresholds by incrementally varying voltage applied to the memory cell transistor, and makes variation of the voltage applied to the memory cell transistor in setting the m-th threshold smaller than variation of the voltage applied to the memory cell transistor in setting the n-th threshold.

4. The device according to claim 3, wherein pulse width of the voltage applied to the memory cell transistor in setting the n-th threshold is narrower than pulse width of the voltage applied to the memory cell transistor in setting the m-th threshold.

5. The device according to claim 1, wherein the width of the distribution of the m-th threshold is half or less of the width of the distribution of the n-th threshold.

6. The device according to claim 1, wherein the width of the distribution of the m-th threshold is third or less of the width of the distribution of the n-th threshold.

7. The device according to claim 1, wherein the control unit sets an erase threshold associated with erase information to a sign different from a sign of the n-th threshold and the m-th threshold.

8. The device according to claim 1, wherein the device includes a plurality of the semiconductor pillars and further comprising:
a connecting portion connecting two of the plurality of semiconductor pillars on one end side.

9. A nonvolatile semiconductor memory device comprising:
a memory unit; and
a control unit,
the memory unit including:
a multilayer structure including a plurality of electrode films and a plurality of interelectrode insulating films alternately stacked in a first direction;
a semiconductor pillar penetrating through the multilayer structure in the first direction;
a storage layer provided between each of the electrode films and the semiconductor pillar;
an inner insulating film provided between the storage layer and the semiconductor pillar;
an outer insulating film provided between each of the electrode films and the storage layer; and
a memory cell transistor to which thresholds corresponding to n-valued information (n being an integer of 3 or more) are set in response to charge accumulated in the storage layer, and
the control unit performing control of setting the thresholds to either positive or negative, and performing control so that, with one of the thresholds most distant from 0 volts being defined as n-th threshold, width of distribution of m-th threshold (m being an integer of 2 or more smaller than n) having a sign being same as the n-th threshold is set narrower than width of distribution of the n-th threshold.

10. The device according to claim 9, wherein the control unit performs control so that the width of the distribution of the m-th threshold (m being an integer of 2 or more smaller than n) is set equal to the width of the distribution of the (m−1)-th threshold.

11. The device according to claim 9, wherein the control unit performs control of setting the width of the distribution of the m-th threshold wider than the width of the distribution of the (m−1)-th threshold.

12. A method for driving a nonvolatile semiconductor memory device, the device including:
a memory unit; and
a control unit,
the memory unit including:
a multilayer structure including a plurality of electrode films and a plurality of interelectrode insulating films alternately stacked in a first direction;
a semiconductor pillar penetrating through the multilayer structure in the first direction;
a storage layer provided between each of the electrode films and the semiconductor pillar;
an inner insulating film provided between the storage layer and the semiconductor pillar;
an outer insulating film provided between each of the electrode films and the storage layer; and
a memory cell transistor to which thresholds corresponding to n-valued information (n being an integer of 2 or more) are set in response to charge accumulated in the storage layer,
the method comprising:
the control unit setting the thresholds to either positive or negative so that, with one of the thresholds most distant from 0 volts being defined as n-th threshold, width of distribution of m-th threshold (m being an integer of 1 or more smaller than n) having a sign being same as the n-th threshold is set narrower than width of distribution of the n-th threshold.

13. The method according to claim 12, wherein the control unit makes number of voltage applications to the memory cell transistor in setting the m-th threshold larger than number of voltage applications to the memory cell transistor in setting the n-th threshold.

14. The method according to claim 12, wherein the control unit performs control of setting the thresholds by incrementally varying voltage applied to the memory cell transistor, and makes variation of the voltage applied to the memory cell transistor in setting the m-th threshold smaller than variation of the voltage applied to the memory cell transistor in setting the n-th threshold.

15. The method according to claim 14, wherein pulse width of the voltage applied to the memory cell transistor in setting the n-th threshold is narrower than pulse width of the voltage applied to the memory cell transistor in setting the m-th threshold.

16. The method according to claim 12, wherein the width of the distribution of the m-th threshold is half or less of the width of the distribution of the n-th threshold.

17. The method according to claim 12, wherein the width of the distribution of the m-th threshold is third or less of the width of the distribution of the n-th threshold.

18. The method according to claim 12, wherein the control unit sets an erase threshold associated with erase information to a sign different from a sign of the n-th threshold and the m-th threshold.

19. The method according to claim 12, wherein the control unit sets the n-th threshold after setting an erase threshold to the memory cell transistor.
